(19) United States
(12) Patent Application Publication
(10) Pub. No.: US 2026/0195496 A1
(43) Pub. Date: Jul. 9, 2026

(54) TOPOLOGY OPTIMIZATION DESIGN METHOD FOR STRUCTURAL RELIABILITY OF MULTIPHASE MATERIALS

(71) Applicant: Southwest Jiaotong University, Chengdu (CN)

(72) Inventors: Run DU, Chengdu (CN); Yizhe LIU, Chengdu (CN); Xuanliang WANG, Chengdu (CN); Min XIE, Chengdu (CN); Yichao YANG, Chengdu (CN); Dong WANG, Chengdu (CN); Zhixian CHENG, Chengdu (CN); Wei XIANG, Chengdu (CN); Wenming CHENG, Chengdu (CN)

(21) Appl. No.: 19/423,661

(22) Filed: Dec. 17, 2025

(30) Foreign Application Priority Data
Jan. 8, 2025 (CN) 202510027297.9

(51) Int. Cl. G06F 30/17

(52) U.S. Cl. CPC G06F 30/17

(57) ABSTRACT

The present application relates to the technical field of structural engineering, and discloses a topology optimization design method for structural reliability of multiphase materials, including: S1, initializing a finite element; S2: setting termination conditions for an outer loop, entering the outer loop, and entering an alternating active-phase algorithm loop; S3: conducting finite element analysis on an element model to obtain a global compliance; S4: analyzing a sensitivity of the global compliance to obtain sensitivities; S5: entering the sensitivity filtering calculation, computing filtered sensitivities by applying a sensitivity filter to the sensitivities; S6: updating density based on the optimization criterion; S7: judging whether iterin equals iterinmax; S8: judging whether b equals M; S9: judging whether a equals M−1; S10: judging an outer-loop termination condition: whether iterout equals iteroutmax.

### CROSS-REFERENCE TO RELATED APPLICATIONS

The present application claims priority to Chinese patent application No. 202510027297.9, filed on Jan. 8, 2025, the entire contents of which are incorporated herein by reference.

### TECHNICAL FIELD

The present application relates to the field of structural engineering design, and in particular to a topology optimization design method for structural reliability of multiphase materials.

### BACKGROUND

Structural optimization refers to the process of achieving optimal structural performance by altering material distribution, dimensions, layout, and connectivity within a predefined design domain, under specified optimization objectives and constraints. It enhances product quality and performance, reduces manufacturing costs, and lowers energy consumption, and has been widely applied in fields such as heavy machinery, agricultural equipment, chemical and metallurgical engineering, civil construction, and transportation. A structural optimization problem is fundamentally defined by three key components: (1) an objective function, which serves as the direct metric for evaluating structural performance; (2) design variables, which are the parameters subject to modification during optimization; and (3) constraints, which impose limits on the allowable values or behaviors of the design variables. From a design perspective, structural optimization can be broadly categorized into three types: size optimization, shape optimization, and topology optimization.

Size optimization involves adjusting only the geometric dimensions of a structure—such as cross-sectional areas of beams, thicknesses of plates, or diameters of internal holes—without altering its shape or topological configuration. Its mathematical model is relatively simple, with limited design variables, and the methodology is now well-established. However, it offers limited innovation potential.

Shape optimization seeks the optimal structural geometry by modifying the boundary configuration (e.g., hole contours or nodal positions) under given loading conditions, objectives, and constraints. A major challenge lies in the fact that shape changes necessitate remeshing of the finite element model, which in turn triggers recomputation of the entire analysis pipeline—including sensitivity analysis of the objective function with respect to design variables—significantly increasing computational cost. Thus, shape optimization is more complex than size optimization, yet it shares similar limitations in terms of design freedom.

Topology optimization, by contrast, determines the optimal material layout within a fixed design domain under prescribed constraints—such as whether voids should exist, where they should be located, and how load-bearing members should be connected. The primary difficulty stems from the fact that feasible topologies are often discrete, non-parametric, and difficult to quantify mathematically. Nevertheless, extensive research has demonstrated that topology-optimized structures exhibit superior efficiency and rationality.

These three optimization approaches correspond naturally to the three classical stages of engineering design: (1) conceptual design, where topology optimization defines the optimal load-path and material layout; (2) basic design, where shape optimization refines the external and internal boundaries; and (3) detailed design, where size optimization fine-tunes dimensional parameters. Clearly, topology optimization plays a central role in this hierarchical design process.

With advances in science, technology, and societal demands, industries such as aerospace and automotive increasingly require lightweight, high-performance, and highly reliable structures with multifunctional characteristics. Traditional single-material topology optimization can no longer meet these complex, diversified requirements. Multiphase (or multi-material) topology optimization has thus emerged as a powerful new paradigm, enabling the simultaneous optimization of structures composed of two or more materials with distinct mechanical properties (e.g., different elastic moduli). This approach has become one of the most active and promising research frontiers in the field of topology optimization.

For instance, existing document one in the prior art—Zuo, W., & Saitou, K. (2017). Multi-material topology optimization using ordered SIMP interpolation. Structural and Multidisciplinary Optimization, 55, 477-491—a classical multiphase topology optimization method based on Ordered Solid Isotropic Material with Penalization (SIMP) interpolation is proposed. This work introduces the original Alternating Active Phase (AAP) algorithm. However, the method suffers from several drawbacks: the resulting optimized structures exhibit blurred material interfaces, a large number of grayscale (intermediate-density) elements, slow convergence, and lack of extension to multi-load-case scenarios.

### SUMMARY

In order to overcome or at least alleviate one or more of the aforementioned technical problems, it is an object of the present application to provide a topology optimization design method for structural reliability of multiphase materials.

The present application provides the following technical solution:

A topology optimization design method for structural reliability of multiphase materials, including:
S1, initializing a finite element by discretizing a design domain into a plurality of elements and setting initial topology optimization parameters, wherein the initial parameters comprise an elastic modulus, a Poisson's ratio, a penalization factor, prescribed volume fractions for each of material phases, a filter radius, and a suppression factor;
S2: setting termination conditions for an outer loop, entering the outer loop, and entering an alternating active-phase algorithm loop, performing inner loops sequentially in an order of a from 1 to p−1 and b from a+1 to p, where a denotes a first material phase in a two-phase loop, b denotes a second material phase in the two-phase loop, and p is the penalization factor;
S3: conducting finite element analysis on an element model to obtain a global compliance;
S4: analyzing a sensitivity of the global compliance to obtain sensitivities;
S5: computing filtered sensitivities by applying a sensitivity filter to the sensitivities;
S6: calculating an iteration factor from filtered sensitivities, judging an iteration factor, and obtaining an updated elemental density for each element;
S7: judging whether iterin equals iterinmax, where iterin and iterinmax respectively denote a current inner-loop iteration count and a maximum allowed inner-loop iteration count; if equal, proceeding to S8; otherwise, returning to S3;
S8: judging whether b equals M, where M denotes a total number of material phases; if equal, proceeding to S9; otherwise, setting b=b+1 and returning to S2;
S9: judging whether a equals M−1; if equal, proceeding to S10; otherwise, setting a=a+1 and returning to S2;
S10: judging an outer-loop termination condition: whether iterout equals iteroutmax, where iterout and iteroutmax respectively denote the current outer-loop iteration count and the maximum allowed outer-loop iteration count; if equal, plotting an elemental density image to obtain the topology optimization result and terminate the outer loop; otherwise, returning to S1.

In one embodiment, in the S3, a multiphase material topology optimization model takes minimum structural compliance as an objective function and volume constraints as constraints, expressed as:

$$\{ \begin{matrix}find & x = {\{ {x}_{1} , {x}_{2} , … , {x}_{n} \}}^{T} ∈ Ω \\ min & C ( x ) = {F}^{T} U = {U}^{T} K U \\ s . t . & F = KU \\ & V ( x ) = {fV}_{0} \\ & 0 < {x}_{min} \leq x < 1\end{matrix} ;$$

in finite element analysis, an elemental stiffness matrix K is:

$$K = {\sum }_{m = 1}^{M} {K}_{m} = {\sum }_{m = 1}^{M} {x}_{m}^{p} {K}_{m}^{0}$$

$${K}_{m} = {\sum }_{m = 1}^{M} {k}_{m}^{e} = {\sum }_{m = 1}^{M} {x}_{m}^{e} {k}_{m}^{0} ;$$

where

$${x}_{m}^{p}$$

denotes a relative volume fraction of a m-th material in element, and

$${K}_{m}^{0}$$

denotes a stiffness matrix of the m-th material; substituting into a mathematical model yields:

$$\{ \begin{matrix}find x = {\{ {x}_{1} , {x}_{2} , , {x}_{M} \}}^{T} ∈ Ω \\ min C ( x ) = {\sum }_{{m = 1}^{}}^{M} {\sum }_{e = 1}^{n} {u}_{e}^{T} {k}_{m}^{e} {u}_{e} = {\sum }_{m = 1}^{M} {\sum }_{e = 1}^{n} {{E}_{m} ( {x}_{m}^{e} )}^{p} {u}_{e}^{T} {k}_{0}^{e} {u}_{e} \\ s . t . F = KU \\ \begin{matrix}{V}_{m} = {\sum }_{e = 1}^{n} {x}_{m}^{e} {v}_{e} \leq {V}_{m}^{0} = {f}_{m} {V}_{0} \\ 0 < {( {x}_{m i n} )}_{m} \leq {x}_{m}^{e} \leq 1\end{matrix}\end{matrix} ;$$

where n is a number of elements, Vₘ is an optimized volume of the m-th material, vₑ is a volume of an element, fₘ is a prescribed volume fraction of the m-th material, uₑ is a nodal displacement vector, F is an applied load vector, K is a global stiffness matrix, C(x) is the global compliance, and x is a volume fraction.

In one embodiment, in the S6, during each iteration, volume constraints Tab for active phase materials a and b are computed as:

$${r}_{ab} = 1 - {\sum }_{{m = 1}_{m \neq \{ a , b \}}}^{M} {α}_{m} ;$$

where αₘ is a volume fraction of a phase material m in each element; since each element contains

$${\sum }_{m = 1}^{M} {α}_{m} = 1 ,$$

once a density of the phase material a is determined, a density of the phase material b is given by:

$${r}_{b} = {r}_{a b} - {r}_{a} ;$$

in a single optimization subproblem, a temporary upper bound for the phase material a is:

$${u}_{a , temp} = min ( {u}_{a} , {r}_{a b} ) ;$$

while a lower bound for the phase material a remains unchanged, two-phase material optimization subproblem is abstractly expressed as:

$$\{ \begin{matrix}min J ( {α}_{a b} , U ( {α}_{ab} ) ) \\ s . t . ℜ ( δ ( {α}_{a b} ) , U ( {α}_{a b} ) ) = 0\end{matrix} .$$

In one embodiment, in the S5, a suppression function based on an exponential function is as follows:

$$δ ( {x}_{e} {B}_{e}^{η} ) = {( {x}_{e} {B}_{e}^{η} )}^{q}$$

$$δ ( {x}_{e} {B}_{e}^{η} ) = \frac{{e}^{q ( {x}_{e} {B}_{e}^{η}} ) - 1}{{e}^{q} - 1} ;$$

where δ(⋅) denotes a suppression function in a design variable update process, q is a suppression factor, and

$${B}_{e}^{η}$$

is an elemental design variable, a design variable update formula in an Optimality Criteria (OC) method with gray-scale element suppression is modified to:

$${x}_{e}^{new} = \{ \begin{matrix}max ( {x}_{m i n} , {x}_{e} - m ) , δ ( {x}_{e} {B}_{e}^{η} ) \leq max ( {x}_{m i n} , {x}_{e} - m ) \\ δ ( {x}_{e} {B}_{e}^{η} ) , max ( {x}_{m i n} , {x}_{e} - m ) \leq δ ( {x}_{e} {B}_{e}^{η} ) \leq min ( 1 , {x}_{e} + m ) \\ min ( 1 , {x}_{e} + m ) , min ( 1 , {x}_{e} + m ) \leq δ ( {x}_{e} {B}_{e}^{η} )\end{matrix} ;$$

when q=1, as q increases, intermediate-density elements are driven toward 0 or 1.

The topology optimization design method for structural reliability of multiphase materials provided by the present application has the following advantages: First, compared with traditional single-material topology optimization, the multiphase material structural reliability topology optimization provides a multi-material topology optimization result, which can address more complex engineering problems such as composite materials. Second, the adopted alternating active-phase algorithm features simple logic, strong scalability, and high computational efficiency. Third, compared with the traditional OC algorithm, the suppression function based on an exponential function adopted in the present application can achieve lower compliance and a smaller proportion of grayscale elements.

### BRIEF DESCRIPTIONS OF THE DRAWINGS

FIG. 1 is a schematic diagram of an optimized structure with clear boundaries provided by an embodiment of the present application.

FIG. 2 is a distribution diagram of a two-phase material structure provided by an embodiment of the present application.

FIG. 3 is a solving sequence diagram of an optimized sub-problem for four-phase materials provided by an embodiment of the present application.

FIG. 4 is a diagram of a power function gray unit suppression function provided by an embodiment of the present application.

FIG. 5 is a diagram of an exponential function gray unit suppression function provided by an embodiment of the present application.

FIG. 6 is a flow chart of topology optimization for multiphase materials provided by an embodiment of the present application.

FIG. 7 is a schematic diagram of a planar MBB beam structure provided by an embodiment of the present application.

FIG. 8 is a schematic diagram of optimized results of an MBB beam using different methods provided by an embodiment of the present application.

FIG. 9 is an iteration curve diagram of the objective function, i.e., compliance value, under three different methods provided by an embodiment of the present application.

FIG. 10 is a comparison table of topology optimization results under different algorithms provided by an embodiment of the present application.

FIG. 11 is a schematic diagram of a planar cantilever beam structure provided by an embodiment of the present application.

FIG. 12 is a schematic diagram of optimized results of a cantilever beam using different methods provided by an embodiment of the present application.

FIG. 13 is an iteration diagram of the objective function using different methods provided by an embodiment of the present application.

FIG. 14 is a comparison table of topology optimization results under different algorithms provided by an embodiment of the present application.

FIG. 15 is a schematic diagram of a three-dimensional cantilever beam structure provided by an embodiment of the present application.

FIG. 16 is an optimized structure diagram of a three-dimensional cantilever beam under each single working condition provided by an embodiment of the present application.

FIG. 17 is an optimized structure diagram of a three-dimensional cantilever beam at different iteration steps provided by an embodiment of the present application.

FIG. 18 is an iteration diagram of the objective function of a three-dimensional cantilever beam structure under each single working condition provided by an embodiment of the present application.

FIG. 19 is an optimized structure diagram of a three-dimensional cantilever beam under different combinations of working condition weight coefficients provided by an embodiment of the present application.

FIG. 20 is a reliability topology optimization structure diagram of a three-dimensional cantilever beam when the working condition weight coefficients are (0.5, 0.5) provided by an embodiment of the present application.

### DETAILED DESCRIPTIONS OF EMBODIMENTS

The technical idea of the present application is as follows:

First, certain idealized premises and assumptions are proposed for each phase of material. For example, during the optimization process, each material inside the discrete element is isotropic, and the properties of each phase of material within the element change with the change of the relative density of the element, following an exponential relationship.

Second, the material design domain is divided into grid elements, and each element is assigned multiphase materials such that the sum of the volume fractions of the multiphase materials equals 1. The alternating active phase algorithm proposed by Tavakoli and Mohseni in 2013 is adopted to perform topology optimization for the combination of different phase materials.

Finally, for the combination of different phase materials, the extended SIMP method is used to establish a material interpolation model for multiphase material topology optimization. The volume fraction of each element is iteratively calculated, and finally, the structural reliability topology optimization result of the multiphase material is obtained, so as to establish a reliable optimized structure of the multiphase material with clear boundaries as shown in FIG. 1.

The present application is described in detail below with reference to the embodiments and the accompanying drawings. However, it should be understood that the embodiments and the accompanying drawings are only used for exemplary description of the present application and do not constitute any limitation on the protection scope of the present application. All reasonable transformations and combinations within the scope of the inventive purpose of the present application fall within the protection scope of the present application.

The present application is further described below with reference to the accompanying drawings.

### Embodiment 1

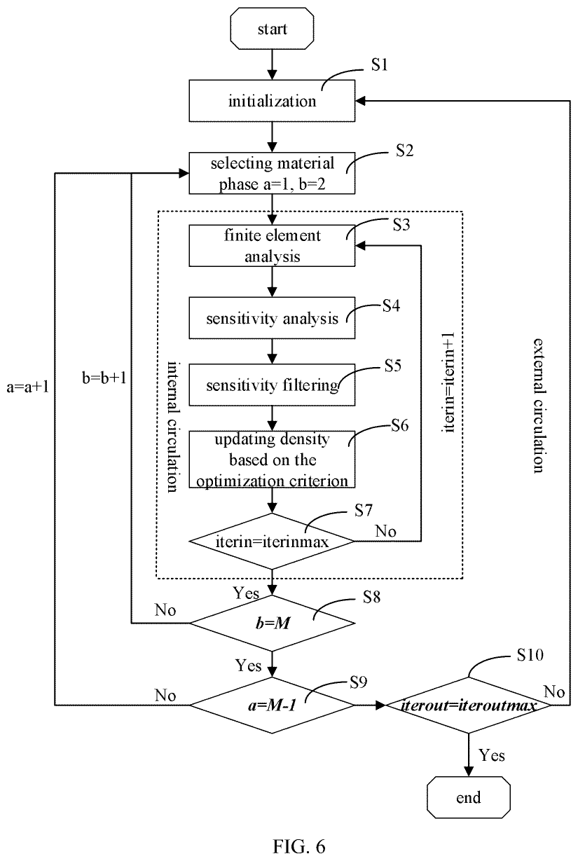

As shown in FIG. 6, the present embodiment provides a topology optimization design method for structural reliability of multiphase materials, which is based on the alternating active phase algorithm. This multiphase material topology optimization includes inner and outer loops, and its core lies in allocating the volume fractions of each material to make the structure achieve the set minimum compliance. The basic steps of the optimization design are as follows:
S1, initializing a finite element by discretizing a design domain into a plurality of elements and setting initial topology optimization parameters, wherein the initial parameters comprise an elastic modulus, a Poisson's ratio, a penalization factor, prescribed volume fractions for each of material phases, a filter radius, and a suppression factor;
S2: setting termination conditions for an outer loop, entering the outer loop, and entering an alternating active-phase algorithm loop, performing inner loops sequentially in an order of a from 1 to p−1 and b from a+1 to p, where a denotes a first material phase in a two-phase loop, b denotes a second material phase in the two-phase loop, and p is the penalization factor;
S3: conducting finite element analysis on an element model to obtain a global compliance;
S4: analyzing a sensitivity of the global compliance to obtain sensitivities;
S5: entering the sensitivity filtering calculation, computing filtered sensitivities by applying a sensitivity filter to the sensitivities;
S6: updating density based on the optimization criterion, calculating an iteration factor from filtered sensitivities, judging an iteration factor, and obtaining an updated elemental density for each element;
S7: judging whether iterin equals iterinmax, where iterin and iterinmax respectively denote a current inner-loop iteration count and a maximum allowed inner-loop iteration count; if equal, proceeding to S8; otherwise, returning to S3;
S8: judging whether b equals M, where M denotes a total number of material phases; if equal, proceeding to S9; otherwise, setting b=b+1 and returning to S2;
S9: judging whether a equals M−1; if equal, proceeding to S10; otherwise, setting a=a+1 and returning to S2;
S10: judging an outer-loop termination condition: whether iterout equals iteroutmax, where iterout and iteroutmax respectively denote the current outer-loop iteration count and the maximum allowed outer-loop iteration count; if equal, plotting an elemental density image to obtain the topology optimization result and terminate the outer loop; otherwise, returning to S1.

S1~S10 are the outer loop, which follows the alternating active phase algorithm; S3~S7 are the inner loop, which is performed in the order of a from 1 to p−1 and b from a+1 to p.

The density update based on the optimization criterion in S6 is specifically the intermediate density element suppression method based on the optimization criterion method: the volume fraction of phase a material is updated through the optimization criterion, and the intermediate density method based on the optimization criterion is applied in this step (see Formula 18 for the specific theory). Note that the sum of the volume fractions of phase a and phase b materials (denoted as r) in this inner loop is obtained by subtracting the volume fractions of all materials except phase a and phase b from the total material volume fraction (1); then the volume fraction of phase b material is obtained by subtracting the volume fraction of phase a material from r. For the specific theoretical part, referring to the alternating active phase algorithm in the existing document one.

In the finite element analysis of Step S3, the simplified material interpolation model is adopted in this embodiment for programming and calculation. The simplified material interpolation function proposed by Tavakoli and Mohseni is as follows:

$${E}_{e} ( {x}_{e} ) = {\sum }_{m = 1}^{M} {x}_{e m}^{p} {E}_{m}^{0} ; \qquad ( 1 )$$

Where m is the number of material phases;

$${E}_{m}^{0}$$

represents the elastic modulus of the phase material; M is the total number of material phases; xₑₘ represents the volume fraction of the m phase material in one element; P is the penalty coefficient; and the sum of the relative volume fractions of each element equals 1:

$${\sum }_{m = 1}^{M} {x}_{e m} = 1 ; \qquad ( 2 )$$

Therefore, the material interpolation function for two-phase material topology optimization is simplified as:

$$E ( x ) = {x}_{1}^{p} {E}_{1} + {x}_{2}^{p} {E}_{2} + {x}_{3}^{p} {E}_{void} ; \qquad ( 3 )$$

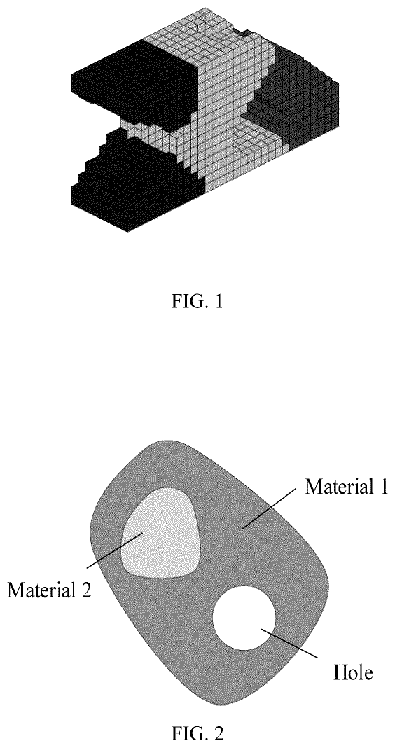

The schematic diagram is shown in FIG. 2.
in the S3, a multiphase material topology optimization model takes minimum structural compliance as an objective function and volume constraints as constraints, expressed as:

$$\{ \begin{matrix}find x = {\{ {x}_{1} , {x}_{2} , … , {x}_{n} \}}^{T} ∈ Ω \\ min C ( x ) = {F}^{T} U = {U}^{T} KU \\ s . t . F = KU \\ V ( x ) = {fV}_{0} \\ 0 < {x}_{min} \leq x < 1\end{matrix} ;$$

It can be known from the multiphase material interpolation formula described in the previous section that in finite element analysis, an elemental stiffness matrix K is:

$$K = {\sum }_{m = 1}^{M} {K}_{m} = {\sum }_{m = 1}^{M} {x}_{m}^{p} {K}_{m}^{0} ;$$

$${K}_{m} = {\sum }_{m = 1}^{M} {k}_{m}^{e} = {\sum }_{m = 1}^{M} {x}_{m}^{e} {k}_{m}^{0} ;$$

where

$${x}_{m}^{p}$$

denotes a relative volume fraction of a m-th material in element, and

$${K}_{m}^{0}$$

denotes a stiffness matrix of the m-th material; substituting into a mathematical model yields:

$$\{ \begin{matrix}find x = {\{ {x}_{1} , {x}_{2} , , {x}_{M} \}}^{T} ∈ Ω \\ min C ( x ) = {\sum }_{m = 1}^{M} {\sum }_{e = 1}^{n} {u}_{e}^{T} {k}_{m}^{e} {u}_{e} = {\sum }_{m = 1}^{M} {\sum }_{e = 1}^{n} {{E}_{m} ( {x}_{m}^{e} )}^{p} {u}_{e}^{T} {k}_{0}^{e} {u}_{e} \\ s . t . F = KU \\ {V}_{m} = {\sum }_{e = 1}^{n} {x}_{m}^{e} {v}_{e} \leq {V}_{m}^{0} = {f}_{m} {V}_{0} \\ 0 < {( {x}_{min} )}_{m} \leq {x}_{m}^{e} \leq 1\end{matrix} ;$$

where n is a number of elements, Vₘ is an optimized volume of the m-th material, vₑ is a volume of an element, fₘ is a prescribed volume fraction of the m-th material, uₑ is a nodal displacement vector, F is an applied load vector, K is a global stiffness matrix, C(x) is the global compliance, and x is a volume fraction. In the optimization model, the first constraint condition is the static equilibrium equation, the second constraint condition is the volume constraint of each phase material, and the third constraint condition means that the relative density of each phase material must comply with the upper and lower bound constraints.

Up to now, various methods have emerged for the development of multiphase material topology optimization in Step 1. The alternating active phase algorithm proposed by Tavakoli and Mohseni in 2013 stands out due to its relatively simple idea, strong scalability, and high computational efficiency. The multiphase material topology optimization model of this embodiment adopts this method, and its abstract expression formula is given below.

First, within the design domain Ω, the material distribution of the m-th phase material is determined by its volume fraction αₘ (m=1, 2, . . . , M), which must satisfy the following relationship:

$${l}_{m} \leq {α}_{m} \leq {u}_{m} ; \qquad ( 8 )$$

$${\sum }_{m = 1}^{M} {α}_{m} = 1 ; \qquad ( 9 )$$

lₘ and uₘ represent the lower bound and upper bound of the volume fraction, respectively, and their values must be between 0 and 1. In addition, each phase material is restricted by a global volume constraint, as shown in the following formula:

$${\int }_{Ω} {α}_{m} dx = {Λ}_{m} \vert Ω \vert , 0 \leq {Λ}_{m} \leq 1 , {\sum }_{m = 1}^{M} {Λ}_{m} = 1 ; \qquad ( 10 )$$

Wherein Λₘ are artificially set volume constraints for each phase material. For the convenience of understanding and calculation, a vector field α={α₁, α₂, . . . , α_{M}} is used to represent the set of design variables. In almost all topology optimization problems, material properties are domain functions of the volume fractions of each material phase in the optimization. The alternating active phase method uses the SIMP interpolation method to describe local material properties; these material parameters are artificially given in advance, and for the simplification of equations, δ(a) is used to represent the material interpolation function for both single-phase and multiphase materials. Partial Differential Equations (PDEs) are also an important part of topology optimization problems; their solutions are represented by U(x)=μ(α(x)), and the partial differential operators of PDE constraints are represented by [symbol] ( . . . ). Therefore, the discrete mathematical model of the multiphase material topology optimization problem is:

$$\{ \begin{matrix}min J ( α , U ( α ) ) \\ s . t . \text{?} ( δ ( α ) , U ( α ) ) = 0\end{matrix} ; \qquad ( 11 )$$

Wherein the objective function J( . . . ) is the integral of α and U within the design domain Ω.

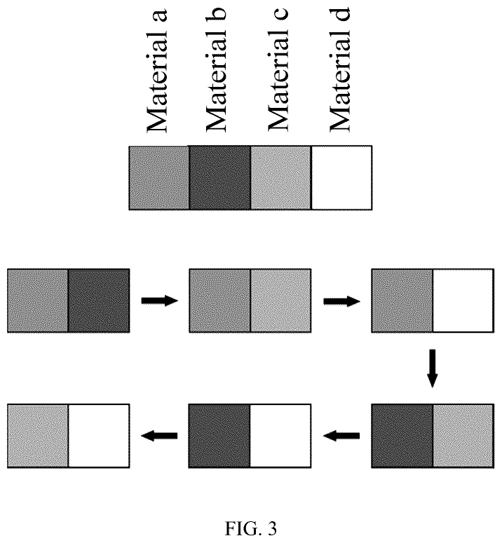

The ingenuity of the alternating active phase algorithm lies in that it decomposes the multiphase material optimization problem into multiple two-phase material topology optimization sub-problems, which are realized through loop nesting. Each outer loop needs to solve M(M−1)/2 sub-problems, and the two-phase material topology optimization structure in each sub-problem is obtained from the two-phase material topology optimization calculation in the previous iteration. As shown in FIG. 3, taking four-phase materials as an example, the solving sequence of the two-phase material sub-problems is given.

The sub-problems in the alternating active phase algorithm of Step S6 in this embodiment are solved based on the variable density method. The superscripts “a” and “b” are used to represent the two-phase materials to be solved in the sub-problems; therefore, the M−2 phase materials except these two phases remain unchanged in the current iteration calculation. Thus, in each iteration calculation, the volume constraints rap of the active phase materials a and b can be calculated by the following formulas:

$${r}_{ab} = 1 - {{\sum }_{m = 1}^{M}}_{m \neq \{ a , b \}} {α}_{m} ; \qquad ( 12 )$$

where αₘ is a volume fraction of a phase material m in each element; since each element contains

$${\sum }_{m = 1}^{M} {α}_{m} = 1 ,$$

once a density of the phase material a is determined, a density of the phase material b is given by:

$${r}_{b} = {r}_{ab} - {r}_{a} ; \qquad ( 13 )$$

It can be noted from the formula (14), in a single optimization subproblem, a temporary upper bound for the phase material a is:

$${u}_{a , temp} = min ( {u}_{a} , {r}_{ab} ) ; \qquad ( 14 )$$

while a lower bound for the phase material a remains unchanged, two-phase material optimization subproblem is abstractly expressed as:

$$\{ \begin{matrix}min J ( {α}_{ab} , U ( {α}_{ab} ) ) \\ s . t . \text{?} ( δ ( {α}_{ab} ) , U ( {α}_{ab} ) ) = 0\end{matrix} . \qquad ( 15 )$$

As we all know, the vast majority of topology optimization methods based on the variable density method have a common problem: the emergence of some intermediate density elements, i.e., gray elements. This numerical instability phenomenon will greatly reduce the manufacturability of the optimized structure. Therefore, in the present application, an intermediate density element suppression method based on the optimization criterion method is adopted. This method is simple to implement and can always satisfy the constraint conditions during the optimization process.

In the S5: Groenwold and Etman proposed in 2007 that when updating design variables using the optimization criterion method, a gray element suppression function is applied to the design variables to exert a certain suppression effect on gray elements. This suppression function is expressed in the form of a power function. Zhang Yifei proposed a suppression function based on an exponential function, as follows:

$$δ ( {x}_{e} {B}_{e}^{η} ) = {( {x}_{e} {B}_{e}^{η} )}^{q} ; \qquad ( 16 )$$

$$δ ( {x}_{e} {B}_{e}^{η} ) = \frac{{e}^{q ( {x}_{e} {B}_{e}^{η} )} - 1}{{e}^{q} - 1} ; \qquad ( 17 )$$

δ(⋅) denotes a suppression function in a design variable update process, q is a suppression factor, and

$${B}_{e}^{η}$$

is an elemental design variable. Therefore, the design variable update formula of the gray element suppression method based on the optimization criterion method can be modified as follows:

$${x}_{e}^{n e w} = \{ \begin{matrix}max ( {x}_{min} , {x}_{e} - m ) , δ ( {x}_{e} {B}_{e}^{η} ) \leq max ( {x}_{min} , {x}_{e} - m ) \\ δ ( {x}_{e} {B}_{e}^{η} ) , max ( {x}_{min} , {x}_{e} - m ) \leq δ ( {x}_{e} {B}_{e}^{η} ) \leq min ( 1 , {x}_{e} - m ) \\ min ( 1 , {x}_{e} - m ) , min ( 1 , {x}_{e} - m ) \leq δ ( {x}_{e} {B}_{e}^{η} )\end{matrix} ; \qquad ( 18 )$$

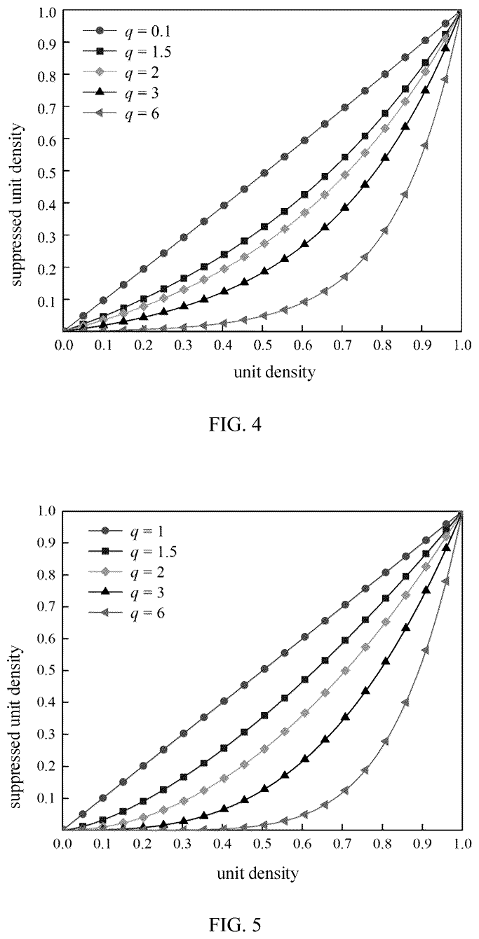

It can be known from Formula 18 that when q=1, it is the original OC algorithm. As the value of q gradually increases, all intermediate density elements approach 0 or 1, as shown in FIGS. 4 and 5.

### Embodiment 1

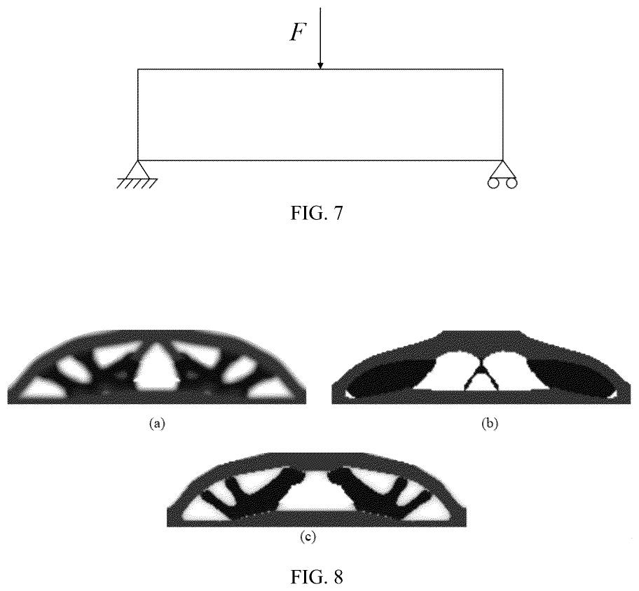

The first example first considers the MBB beam structure shown in FIG. 7, with an aspect ratio of 4:1 and geometric dimensions of 192 mm×48 mm. The structure is discretized into 192×48 elements. The horizontal and vertical displacements are constrained at the bottom left corner of the structure, the vertical displacement is constrained at the bottom right corner, and a vertical concentrated force of 1 N is applied at the midpoint of the upper edge.

First, the optimization problem of two-phase solid materials is considered: red represents solid material 1 with an elastic modulus set to 2 and a volume fraction set to 0.4; blue represents solid material 2 with an elastic modulus of 1 and a volume fraction of 0.2; the hole material is white/colorless with an elastic modulus set to 1e-9 and a volume fraction of 0.4.

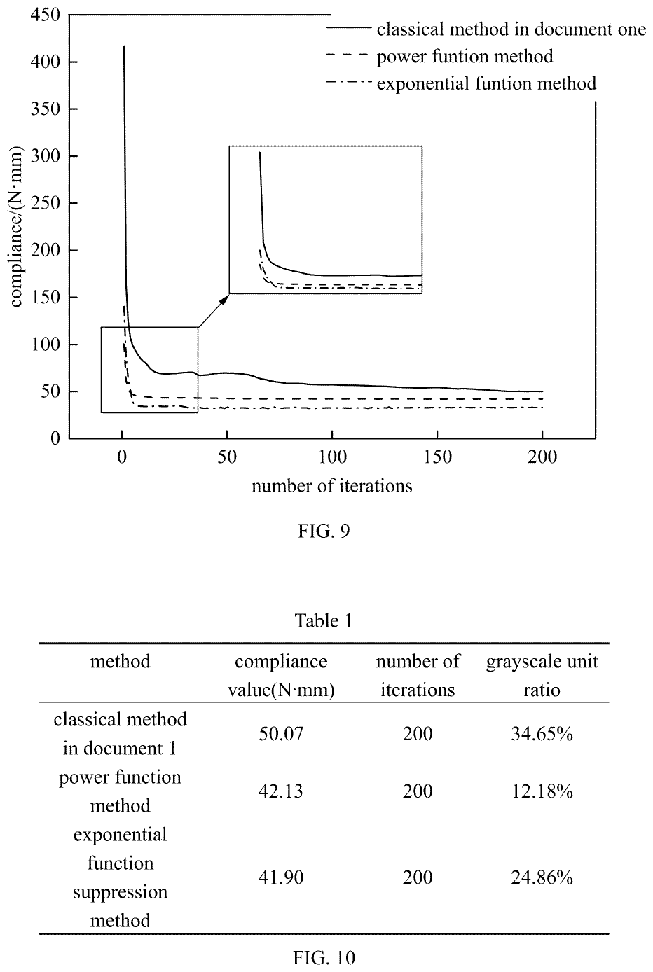

The results of the classic alternating active phase algorithm in the existing document one, the gray element suppression method based on the power function, and the gray element suppression method based on the exponential function are analyzed and compared to select the most suitable method. The initial value of the suppression factor q is set to 1, and its growth step size is 0.01 per cycle. The optimization results are shown in FIG. 8, where FIG. 8.a is the classic algorithm in Literature 1; FIG. 8.b is the gray element suppression method based on the power function; FIG. 8.c is the gray element suppression method based on the exponential function; and FIG. 9 is the iteration curve diagram of the objective function, i.e., compliance value, under the three methods.

Table 1 in FIG. 10 lists the optimization result data filtered by three different algorithms under the same parameters, including the objective function value, number of iterations, and proportion of gray elements.

As shown in FIG. 8, all three algorithms can optimize a complete multiphase material MBB beam structure. Their common feature is that solid material 1 with a larger elastic modulus is distributed around the beam, and the middle support part is filled with solid material 2 with a smaller elastic modulus. There are only slight differences in the specific structural details between the results of different methods. However, overall, materials with high stiffness are basically distributed on the main force transmission paths of the structure, which verifies the effectiveness of the alternating active phase algorithm and proves that the algorithm can improve material utilization efficiency while ensuring the overall performance of the structure. In addition, it can be clearly seen that compared with the original alternating active phase algorithm in the existing document one, both the gray element suppression method based on the power function and the one based on the exponential function can obtain optimized structures with clearer boundaries, which can be more intuitively seen from the proportion of gray elements in Table 1 of FIG. 10.

From FIG. 9, the objective function iteration curves under the three methods can be seen. Combined with the data in Table 1 of FIG. 10, it can be observed that the objective functions under the three methods gradually converge at approximately the 10th iteration. However, the final objective function value of the original alternating active phase algorithm is the largest, followed by that of the power function suppression method, and the exponential function method has the smallest value. This indicates that the structure optimized by the original alternating active phase algorithm has the lowest stiffness, while the structure optimized by the gray element suppression method based on the exponential function has the highest stiffness.

### Embodiment 2

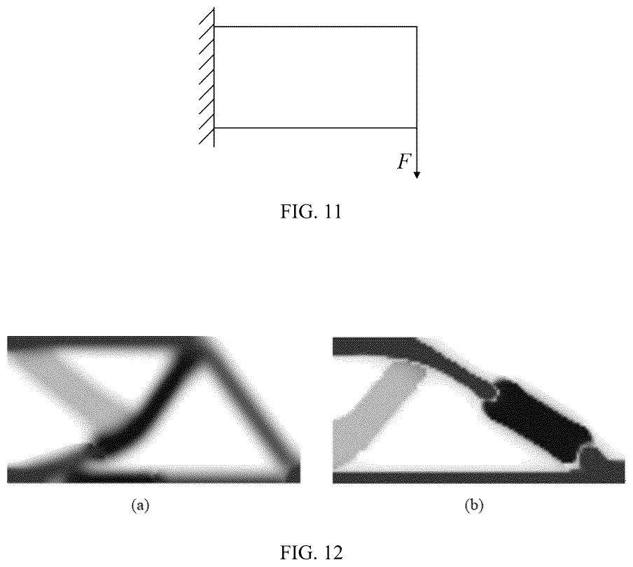

The second example considers the planar cantilever beam structure shown in FIG. 11, with an aspect ratio of 2:1 and geometric dimensions of 96 mm×48 mm. The structure is discretized into 96×48 elements. The left end of the beam is constrained by a fixed support, and a concentrated force of unit magnitude is applied at the bottom right corner.

In this example, the optimization problem of three-phase solid materials is considered: red represents solid material 1 with an elastic modulus set to 5 and a volume fraction set to 0.2; blue represents solid material 2 with an elastic modulus of 3 and a volume fraction of 0.1; green represents solid material 3 with an elastic modulus set to 1 and a volume fraction of 0.1; the hole material is white/colorless with an elastic modulus set to 1e-9 and a volume fraction of 0.6. Other parameters, such as the suppression factor and cycle step size, are set the same as in the first example. The results are shown in FIG. 12, where FIG. 12.a is the result of the classic method in the existing document one, and FIG. 12.b is the gray element suppression method based on the exponential function.

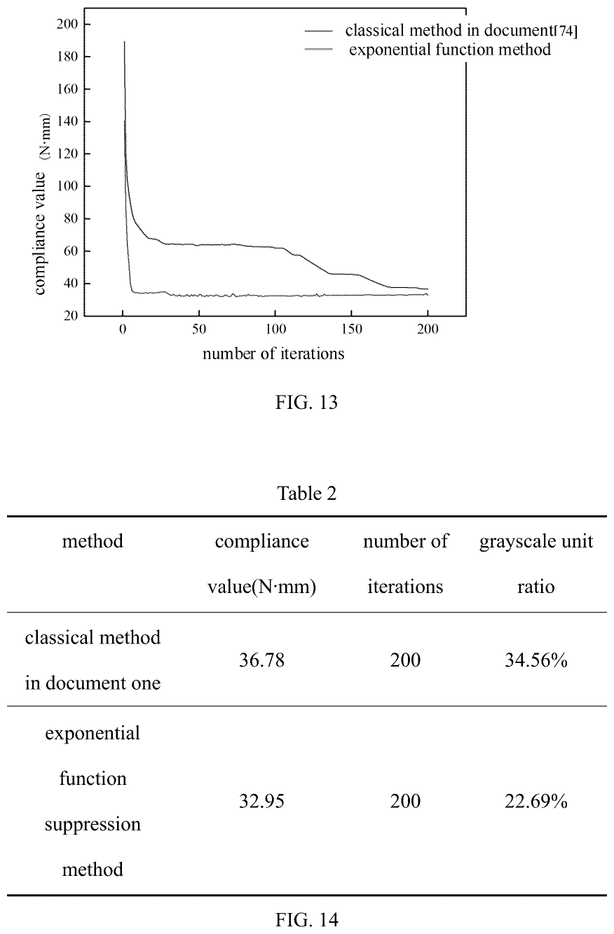

Similar to the previous example, the objective function iteration curves under the two methods are first plotted, and then the objective function values, number of iterations, and proportion of gray elements of the optimization results under the two different algorithms are listed, as shown in FIG. 13.

It can be clearly seen from Table 1 in FIG. 14 that the gray element suppression method based on the exponential function obtains a clearer optimized structure diagram, and its final objective function value is smaller than that obtained by the original alternating active phase method. In summary, both gray element suppression methods can effectively suppress gray elements to obtain clearer structures. Although the gray element suppression method based on the power function has the lowest proportion of gray elements in the optimized structure, it sometimes produces some small branch structures and large block structures, which are less reasonable than the gray element suppression method based on the exponential function. Moreover, the stiffness of the optimized structure is lower than that of the exponential function suppression method. Therefore, the multiphase material optimization models in the subsequent chapters all adopt the gray element suppression method based on the exponential function to suppress the numerical instability phenomenon of gray elements.

### Embodiment 3

The last example also extends the two-dimensional multiphase material topology optimization problem to a three-dimensional one. This code is modified on the basis of the two-dimensional multi-material code with reference to the classic single-phase material three-dimensional code. Except for the different finite element parts, its core idea and basic process are completely consistent.

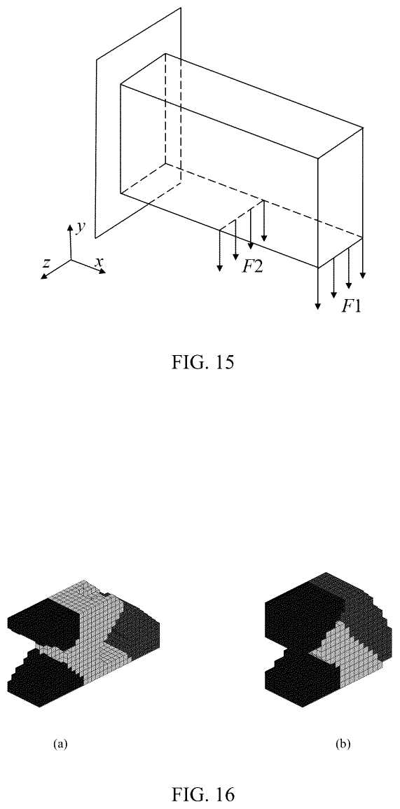

Considering that the three-dimensional cantilever beam structure shown in the figure, with geometric dimensions of 30 cm×15 cm×8 cm. The left boundary of the structure is fully constrained, and the working condition loads F1 and F2 are shown in FIG. 15, both with a magnitude of 1 N. The structure is discretized into 3600 elements, the penalty coefficient is set to 3, and the filter radius is set to 5.

This example considers the topology optimization problem of three-phase solid materials: solid material 1 is red with an elastic modulus set to 5 and a volume fraction of 0.16; solid material 2 is blue with an elastic modulus of 2 and a volume fraction of 0.16; solid material 3 is green with an elastic modulus set to 1 and a volume fraction of 0.16.

FIG. 16 shows the optimized structure of the cantilever beam under single working conditions, where FIG. 16.a is the optimization result of Working Condition 1, and FIG. 16.b is the optimization result of Working Condition 2. It can be seen from the figures that the structures under both working conditions are clear and reasonable. When the working condition load F1 acts alone, the area around the load application point is filled with red material with the largest elastic modulus (i.e., the highest stiffness), the part connected to the fixed end is filled with blue material with a slightly smaller elastic modulus, and the middle part is filled with green material with the smallest elastic modulus. The optimized structure of Working Condition 2 also follows this rule, but its geometric dimensions are different. This is because the maximum stress of the cantilever beam structure is concentrated at the load application point and the contact point with the fixed end, so these main force-bearing parts should be filled with materials with large elastic modulus, which is consistent with the rules and results obtained from the two-dimensional cantilever beam example in Chapter 4. It further verifies the effectiveness of this three-dimensional multi-material method.

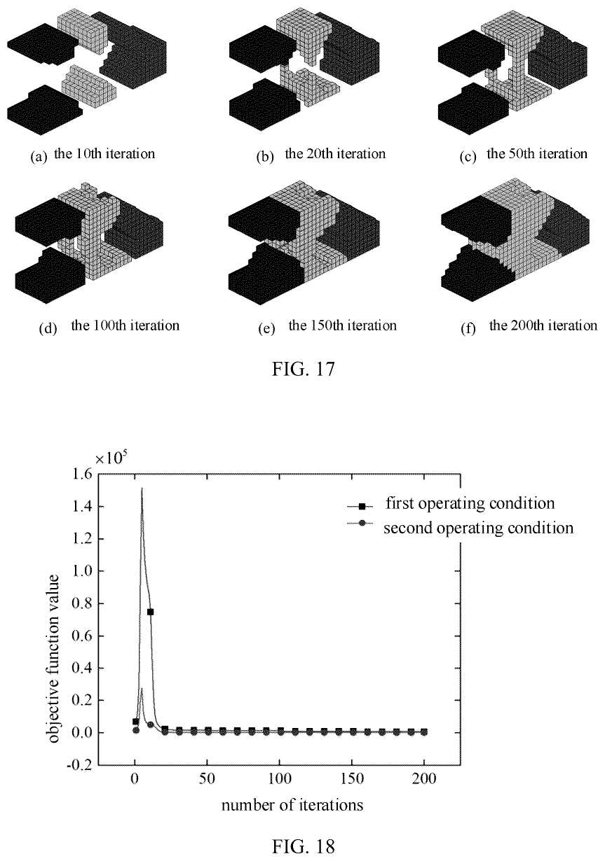

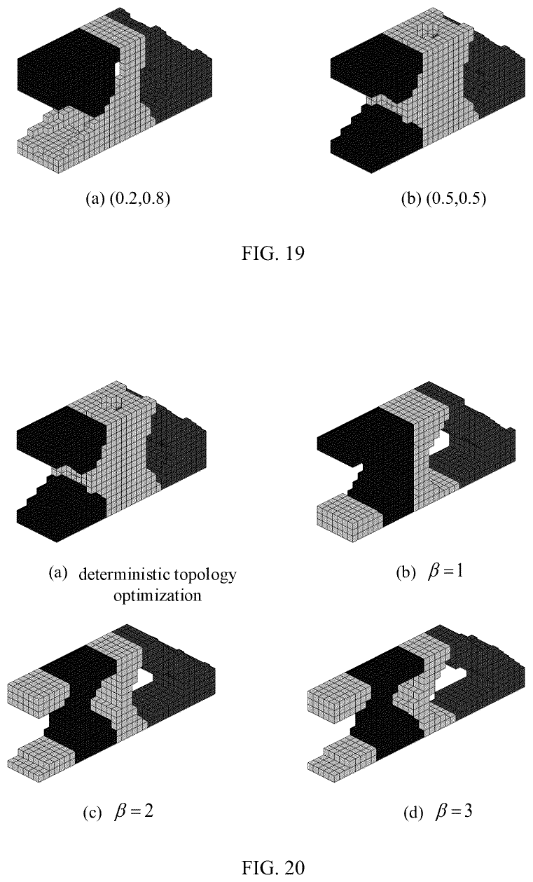

Six iteration steps (10th, 20th, 50th, 100th, 150th, and 200th) are selected to further show their optimization processes, as shown in FIG. 17. The multi-working-condition topology optimization structure can be further obtained from the structure obtained by single-working-condition topology optimization. Here, two combinations of working condition weight coefficients (ω₁, ω₂) are selected for calculation, which are set to (0.2, 0.8) and (0.5, 0.5) respectively, as shown in FIG. 19. Further, the second set of working condition weight coefficients is selected, and the optimized structures under different β values are listed, as shown in FIG. 18. It can be seen from FIG. 20 that, similar to the two-dimensional examples calculated earlier, the configuration of the reliability topology optimization structure is basically the same as that of the deterministic topology optimization structure. For multiphase materials, their material distribution is also basically unchanged. However, their geometric dimensions will undergo slight changes: as the β increases, the structural length becomes larger, the width and height become smaller, and the volume fraction decreases.

The above embodiments are only preferred implementations of the present application, and the protection scope of the present application is not limited to the above embodiments. All technical solutions under the idea of the present application belong to the protection scope of the present application. It should be pointed out that improvements and modifications made by those skilled in the art without departing from the principles of the present application should also be regarded as the protection scope of the present application.

What is claimed is:

1. A topology optimization design method for structural reliability of multiphase materials, comprising:
S1, initializing a finite element by discretizing a design domain into a plurality of elements and setting initial topology optimization parameters, wherein the initial parameters comprise an elastic modulus, a Poisson's ratio, a penalization factor, prescribed volume fractions for each of material phases, a filter radius, and a suppression factor;
S2: setting termination conditions for an outer loop, entering the outer loop, and entering an alternating active-phase algorithm loop, performing inner loops sequentially in an order of a from 1 to p−1 and b from a+1 to p, where a denotes a first material phase in a two-phase loop, b denotes a second material phase in the two-phase loop, and p is the penalization factor;
S3: conducting finite element analysis on an element model to obtain a global compliance;
S4: analyzing a sensitivity of the global compliance to obtain sensitivities;
S5: computing filtered sensitivities by applying a sensitivity filter to the sensitivities;
S6: calculating an iteration factor from filtered sensitivities, judging an iteration factor, and obtaining an updated elemental density for each element;
S7: judging whether iterin equals iterinmax, where iterin and iterinmax respectively denote a current inner-loop iteration count and a maximum allowed inner-loop iteration count;
if equal, proceeding to S8; otherwise, returning to S3;
S8: judging whether b equals M, where M denotes a total number of material phases; if equal, proceeding to S9; otherwise, setting b=b+1 and returning to S2;
S9: judging whether a equals M−1; if equal, proceeding to S10; otherwise, setting a=a+1 and returning to S2;
S10: judging an outer-loop termination condition: whether iterout equals iteroutmax, where iterout and iteroutmax respectively denote the current outer-loop iteration count and the maximum allowed outer-loop iteration count; if equal, plotting an elemental density image to obtain the topology optimization result and terminate the outer loop; otherwise, returning to S1.

2. The topology optimization design method for structural reliability of multiphase materials according to claim 1, wherein
in the S3, a multiphase material topology optimization model takes minimum structural compliance as an objective function and volume constraints as constraints, expressed as:
$$\{ \begin{matrix}find & x = {\{ {x}_{1} , {x}_{2} , … , {x}_{n} \}}^{T} ∈ Ω \\ min & C ( x ) = {F}^{T} U = {U}^{T} K U \\ s . t . & F = KU \\ & V ( x ) = {fV}_{0} \\ & 0 < {x}_{min} \leq x < 1\end{matrix} ;$$
in finite element analysis, an elemental stiffness matrix K is:
$$\begin{matrix}K = {\sum }_{m - 1}^{M} {K}_{m} = {\sum }_{m = 1}^{M} {x}_{m}^{p} {K}_{m}^{0} \\ {K}_{m} = {\sum }_{m = 1}^{M} {k}_{m}^{e} = {\sum }_{m = 1}^{M} {x}_{m}^{e} {k}_{m}^{0}\end{matrix} ;$$
where
$${x}_{m}^{p}$$
denotes a relative volume fraction of a m-th material in element, and
$${K}_{m}^{0}$$
denotes a stiffness matrix of the m-th material; substituting into a mathematical model yields:
$$\{ \begin{matrix}find & x = {\{ {x}_{1} , {x}_{2} , … , {x}_{M} \}}^{T} ∈ Ω \\ min & C ( x ) = {\sum }_{m = 1}^{M} {\sum }_{e = 1}^{n} {u}_{e}^{T} {k}_{m}^{e} {u}_{e} = {\sum }_{m = 1}^{M} {\sum }_{e = 1}^{n} {{E}_{m} ( {x}_{m}^{e} )}^{p} {u}_{e}^{T} {k}_{0}^{e} {u}_{e} \\ s . t . & F = KU \\ & {V}_{m} = {\sum }_{e = 1}^{n} {x}_{m}^{e} {v}_{e} \leq {V}_{m}^{0} = {f}_{m} {V}_{0} \\ & 0 < {( {x}_{min} )}_{m} \leq {x}_{m}^{e} < 1\end{matrix} ;$$
where n is a number of elements, Vₘ is an optimized volume of the m-th material, vₑ is a volume of an element, fₘ is a prescribed volume fraction of the m-th material, uₑ is a nodal displacement vector, F is an applied load vector, K is a global stiffness matrix, C(x) is the global compliance, and x is a volume fraction.

3. The topology optimization design method for structural reliability of multiphase materials according to claim 1, wherein
in the S6, during each iteration, volume constraints r_{ab} for active phase materials a and b are computed as:
$${r}_{a b} = 1 - {\sum }_{{m = 1}_{m \neq \{ a , b \}}}^{M} {α}_{m} ;$$
where αₘ is a volume fraction of a phase material m in each element; since each element contains
$${\sum }_{m = 1}^{M} {α}_{m} = 1 ,$$
once a density of the phase material a is determined, a density of the phase material b is given by:
$${r}_{b} = {r}_{a b} - {r}_{a} ;$$
in a single optimization subproblem, a temporary upper bound for the phase material a is:
$${u}_{a , temp} = min ( {u}_{a} , {r}_{a b} ) ;$$
while a lower bound for the phase material a remains unchanged, two-phase material optimization subproblem is abstractly expressed as:
$$\{ \begin{matrix}min & J ( {α}_{a b} , U ( {α}_{ab} ) ) \\ s . t . & \text{?} ( δ ( {α}_{a b} ) , U ( {α}_{a b} ) ) = 0\end{matrix} .$$

4. The topology optimization design method for structural reliability of multiphase materials according to claim 1, wherein
in the S5, a suppression function based on an exponential function is as follows:
$$\begin{matrix}δ ( {x}_{e} {B}_{e}^{η} ) = {( {x}_{e} {B}_{e}^{η} )}^{q} \\ δ ( {x}_{e} {B}_{e}^{η} ) = \frac{{e}^{q ( {x}_{e} {B}_{e}^{η} )} - 1}{{e}^{q} - 1}\end{matrix} ;$$
where δ(⋅) denotes a suppression function in a design variable update process, q is a suppression factor, and
$${B}_{e}^{η}$$
is an elemental design variable, a design variable update formula in an Optimality Criteria (OC) method with gray-scale element suppression is modified to:
$${x}_{e}^{n e w} = \{ \begin{matrix}max ( {x}_{min} , {x}_{e} - m ) , δ ( {x}_{e} {B}_{e}^{η} ) \leq max ( {x}_{min} , {x}_{e} - m ) \\ δ ( {x}_{e} {B}_{e}^{η} ) , max ( {x}_{min} , {x}_{e} - m ) \leq δ ( {x}_{e} {B}_{e}^{η} ) \leq min ( 1 , {x}_{e} - m ) \\ min ( 1 , {x}_{e} - m ) , min ( 1 , {x}_{e} - m ) \leq δ ( {x}_{e} {B}_{e}^{η} )\end{matrix} ;$$
when q=1, as q increases, intermediate-density elements are driven toward 0 or 1.
